(19) United States
(12) Patent Application Publication
(10) Pub. No.: US 2012/0280305 A1
(43) Pub. Date: Nov. 8, 2012

(54) FLASH MEMORY DEVICE AND MANUFACTURING METHOD THEREOF

(75) Inventors: Huilong Zhu, Poughkeepsie, NY (US); Zhijiong Luo, Poughkeepsie, NY (US); Haizhou Yin, Poughkeepsie, NY (US)

(73) Assignee: INSTITUTE OF MICROELECTRONICS, CHINESE ACADEMY OF SCIENCES, BEIJING (CN)

(21) Appl. No.: 13/062,024

(22) PCT Filed: Sep. 26, 2010
(86) PCT No.: PCT/CN10/77296

§ 371 Date: Mar. 3, 2011

(30) Foreign Application Priority Data
May 7, 2009 (CN) 201010171371.8

(51) Int. Cl. H01L 29/792; H01L 21/336

(52) U.S. Cl. 257/324; 438/287; 257/E29.309; 257/E21.423

(57) ABSTRACT

The present invention discloses a flash memory device. The flash memory device comprises a semiconductor substrate and a flash memory area located on the semiconductor substrate. The flash memory area comprises a first doped well, which is divided into a first region and a second region by an isolation region, the second region being doped with an impurity having an electrical conductivity opposite to that of the first doped well; a high-k gate dielectric layer located on the first doped well; and a metal layer located on the high-k gate dielectric layer. The present invention enables compatibility between the high-k dielectric metal gate and the erasable flash memory and increases the operation performance of the flash memory. The present invention also provides a manufacturing method of the flash memory device, which greatly increases the production efficiency and yield of flash memory devices.

### FIELD OF THE INVENTION

The present invention relates to the technical field of semiconductor manufacturing, in particular to a flash memory device and a manufacturing method thereof.

### DESCRIPTION OF THE PRIOR ART

With the rapid development of computer technology, higher requirements are set forth to the performance of semiconductor memory devices. Semiconductor memory devices for storing data can be classified into two categories, i.e. volatile memory devices and non-volatile memory devices. Volatile memory devices will lose the stored data after interruption of the power supply, while non-volatile memory devices will still keep the stored data therein after interruption of the power supply. A flash memory is a non-volatile storage integrated circuit developed from erasable and programmable read-only memory (EPROM) and electrically erasable and programmable read-only memory (EEPROM). The flash memory is a one-time programmable (OTP) device having such main advantages as fast operation speed, small cell area, high integration level and good reliability, and so on, so it has extensive application prospects in the field of smart card, microcontroller or the like.

In recent years, there is an increasing use of Hf element based high-k materials in the semiconductor manufacturing process to replace the silicon dioxide as the gate dielectric layer, which not only significantly increases the operation performance of the semiconductor devices, but also reduces electric current waste and energy loss, thus bringing great progress to the semiconductor manufacturing process.

However, while introducing the high-k dielectric metal gate process into the conventional process of making flash memories using complementary metal-oxide semiconductor (CMOS), the flash memory is greatly influenced in its erasability and cannot be repeatedly read and written for many times because data stored in the metal gate formed in the high-k dielectric metal gate process will not be easily erased by electric current. As a result, there is a big challenge when applying the high-k dielectric metal gate process to the process of manufacturing of a one-time programmable (OTP) device.

### SUMMARY OF THE INVENTION

The object of the present invention is to provide a semiconductor structure that is compatible with the high-k dielectric metal gate process and a manufacturing method thereof, so as to overcome the defect in the prior art.

To achieve the object, the present invention provides a flash memory device which comprises a semiconductor substrate and a flash memory area located on the semiconductor substrate. The flash memory area comprises: a first doped well, which is divided into a first region and a second region by an isolation region, the second region being doped with an impurity having an electrical conductivity opposite to that of the first doped well; a high-k gate dielectric layer located on the first doped well; and a metal layer located on the high-k gate dielectric layer.

The advantageous effect of the present invention is that the flash memory device comprises a polysilicon layer in the metal gate stack of the transistor area, which realizes the compatibility between the high-k dielectric metal gate and the erasable flash memory and makes it possible to apply the high-k dielectric metal gate into the one-time programmable (OTP) device so as to increase the operation performance of the flash memory.

Accordingly, the present application also provides a manufacturing method of the flash memory device. The method comprises the steps of providing a semiconductor substrate; forming a flash memory area on the substrate, the flash memory area comprising a first doped well, the first doped well being divided into a first region and a second region by an isolation region, the second region being doped with an impurity having an electrical conductivity opposite to that of the first doped well; forming a high-k gate dielectric layer and a metal layer on the first doped well.

The method of manufacturing the flash memory according to the present invention enables compatibility with the high-k dielectric metal gate process. Since the floating gate of the flash memory and the metal gate of the transistor adopt the same material and laminated structure, the same steps could be adopted in the methods of forming the flash memory and the transistor respectively on the same substrate. As a result, the process flow is greatly simplified and the production efficiency and homogeneity of products are increased, thereby providing favorable conditions for large-scale industrial production.

### BRIEF DESCRIPTION OF DRAWINGS

The advantages of the above and/or additional aspects of the present invention will become apparent and easily understood from the following descriptions of the embodiments in conjunction with the accompany drawings, in which:

FIG. 1 is a schematic view of a flash memory device according to an embodiment of the present invention;

FIGS. 2-11 are sectional views of the device structures in the intermediate steps of a manufacturing method of the flash memory device according to an embodiment of the present invention.

### DETAILED DESCRIPTION OF THE INVENTION

The embodiments of the present invention will be described in detail below, examples of which are shown in the drawings. The same or similar reference number indicates the same or similar element or the element having the same or similar function throughout the drawings. The embodiments described below with reference to the drawings are exemplary, and they are only for the purpose of illustrating the present invention rather than limiting the present invention.

The flash memory device of the present invention uses a metal gate electrode layer in the transistor area, which can not only overcome the defect of poor electrical erasability of the metal gate manufactured according to the high-k dielectric metal gate process, but also uniform the manufacturing processes of the flash memory and the transistor. Thus the manufacturing steps are simplified and the production efficiency is increased, and the flash memory made by the high-k dielectric metal gate process can be applied into the OTP device. In order to facilitate a clearer understanding of the idea of the present invention, it will be described in detail below using preferred embodiments.

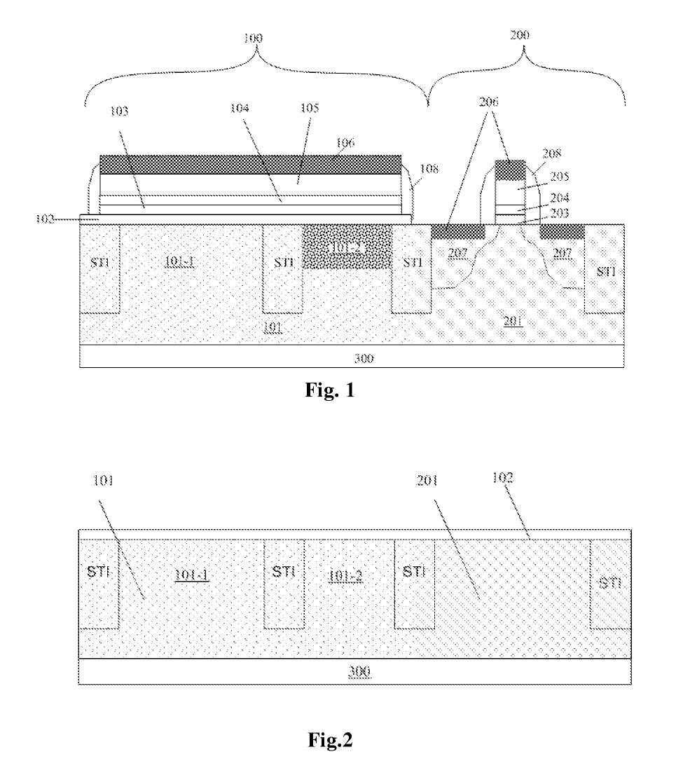

FIG. 1 shows a flash memory device of the present invention. The device comprises a substrate 300, for example, a bulk silicon substrate; a flash memory area 100 formed on the substrate 300, the flash memory area comprising a first doped well 101 which is divided into a first region 101-1 and a second region 101-2 by an isolation region (STI (Shallow Trench Isolation) as shown in FIG. 1), the second region 101-2 being doped with an impurity having an electrical conductivity opposite to that of the first doped well; a high-k gate dielectric layer 103 located on the first doped well; and a metal layer 104 located on the high-k gate dielectric layer.

Particularly, the first doped well 101 is P-type doped, and the impurity in the second region 101-2 is P, As or a combination thereof. Particularly, if the first doped well 101 is N-type doped, then the impurity in the second region 101-2 is B, Ga, In or any combination thereof.

Optionally, the device also comprises a polysilicon 105 located on the metal layer. There is also an oxide layer 102 on the substrate in the area of the flash memory.

The high-k gate dielectric layer 103 may include an HfO₂ layer having a thickness of about 1-4 nm. The metal layer 104 may include a TiN layer having a thickness of 3-10 nm. Of course, those skilled in the art can choose equivalent substitute materials of said materials as required in practice, while the present invention does not make any limitation thereto. For example, the material may be any one or more of TaC, TiN, TaTbN, TaErN, TaYbN, TaSiN, HfSiN, MoSiN, RuTaₓ, NiTaₓ, MoNₓ, TiSiN, TiCN, TaAlC, TiAlN, TaN, PtSiₓ, Ni₃Si, Pt, Ru, Ir, Mo, HfRu and RuOₓ. In particular, the device may further comprise a metal silicide layer 106, such as a NiSi layer, on the polysilicon 105.

The existence of the metal layer 104 enables compatibility between the flash memory device and the high-k metal gate process.

In another embodiment of the present invention, a buried oxide region 301 is formed on the semiconductor substrate, and the flash memory area is formed on the buried oxide region 301, as shown in FIG. 11.

Particularly, the device further comprises a transistor area 200 that is separated from the flash memory area 100 by an isolation region. The transistor area 200 includes a second doped well 201, which can be doped with an impurity having an electrical conductivity same as or opposite to that of the first doped well, and a high-k gate dielectric layer 203 and a metal layer 204 located on the substrate in the transistor area. The transistor area 200 further includes a source region 207 and a drain region 207. Optionally, the transistor area further includes a polysilicon 205 located on the metal layer 204.

The high-k gate dielectric layer 203 may include an HfO₂ layer having a thickness of about 2-4 nm. The metal layer 204 may include a TiN layer having a thickness of 3-10 nm. Of course, those skilled in the art can choose equivalent substitute materials of said materials as required in practice, while the present invention does not make any limitation thereto. In particular, the device may further comprise a metal silicide layer 206, such as a NiSi layer, on the polysilicon 205 and the source region 207 and the drain region 207.

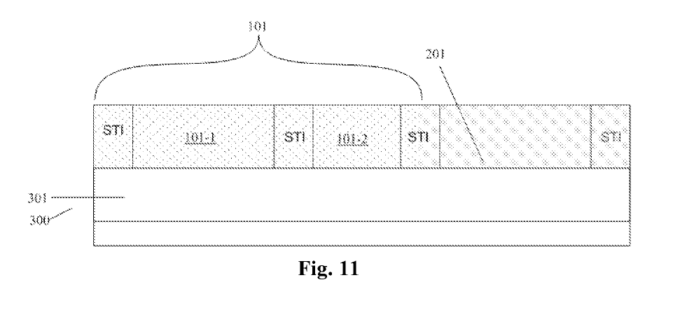

Particularly, the gate stacks of the flash memory area and of the transistor area can be formed in the same process so as to be compatible with the manufacturing process of the high-k gate stack. Optionally, said flash memory device also comprises an inter-layer dielectric layer covering the device and metal silicide contacts on the source region and the drain region of the transistor area, as shown by 206 in FIG. 10.

The method of manufacturing the flash memory device of the present invention as shown in FIG. 1 will be described in detail with reference to the drawings hereinafter. Of course, the present invention can use specific steps and processes that are different from those described below to manufacture the flash memory device, but these steps and processes are all within the protection scope of the present invention.

First, a semiconductor substrate 300 is provided in step 1. As shown in FIG. 2, a semiconductor substrate 300 is provided first, and at least two shallow trench isolations (STI) are formed on the substrate 300 to isolate a flash memory area from a transistor area, both of which will subsequently be formed by implantation, and to isolate a first region from a second region both of which will be formed in the flash memory area by implantation.

Then in step 2, a flash memory area 100 is formed on the substrate. The flash memory area comprises a first doped well 101 which is divided into a first region 101-1 and a second region 101-2 by an isolation region The second region 101-2 is doped with an impurity having an electrical conductivity opposite to that of the first doped well. To be specific, well implantation can be performed on the substrate 300 to form a first doped well region 101. For example, a p-type dopant can be used for implanting the substrate in the entire flash memory area 100, so the flash memory area is also referred to as a p-well region below. Afterwards, an impurity of a second doping type is used for implanting the second region 101-2.

The second doping type is opposite to the first doping type, and for example, P, As or a combination thereof can be used. The first doped well 101 can be formed by making a patterned mask, performing photolithography and then performing ion implantation, for example.

Optionally, in order to be compatible with the process flow of the transistor area, the present invention may alternatively comprise a transistor area 200, which comprises a second doped well 201 that is isolated from the first doped well by the isolation region. The second doped well is doped with an impurity having an electrical conductivity opposite to that of the first doped well. For example, an n-type dopant may be used for implanting the substrate in the entire transistor area 200, so the transistor area is also referred to as an n-well region below.

The first doped well of the flash memory area and the second doped well of the transistor area can be formed by means of photolithography and ion implantation. Of course, they can also be formed by other means, which are all within the protection scope of the present invention.

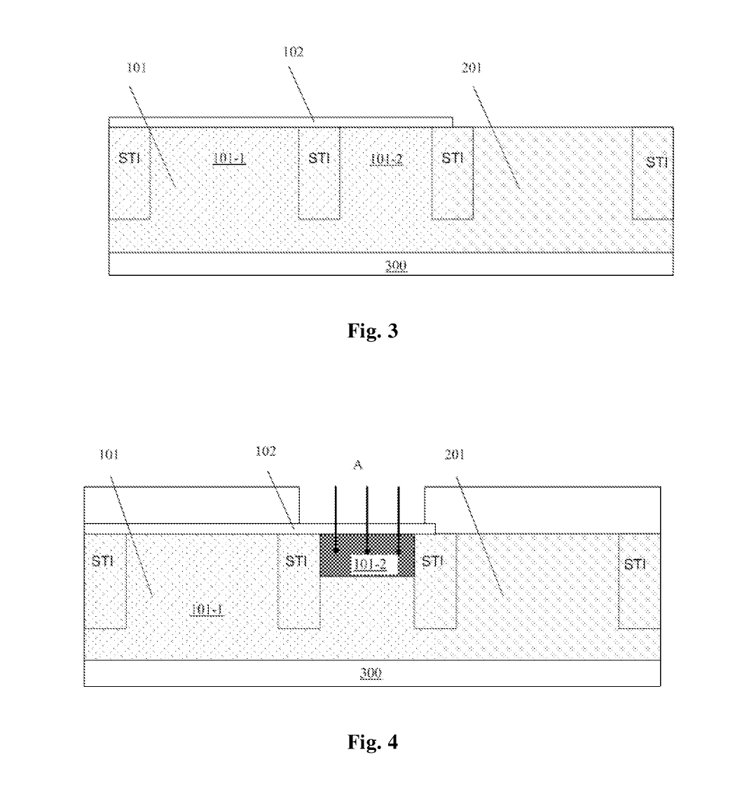

Optionally, an oxide layer 102 can be formed on the substrate in the flash memory area, of which the thickness is preferably 1-20 nm. Specifically, the p-well region and the n-well region can be formed in the substrate first, and then the oxide layer 102 is formed on the substrate, as shown in FIG. 2. The oxide layer in the transistor area 200 is removed and the oxide layer on the flash memory area is retained by performing photolithography, as shown in FIG. 3. After that, as shown in FIG. 4, a patterned photoresist is formed again, and element As or P is implanted into the second region 101-2 in the p-well region 101 in the direction of angle A. Then, the photoresist is removed.

In this step, the oxide layer 102 is not indispensable, that is, the step of forming the oxide layer 102 may be omitted in some processes. But adding the oxide layer 102 can effectively reduce the leakage current.

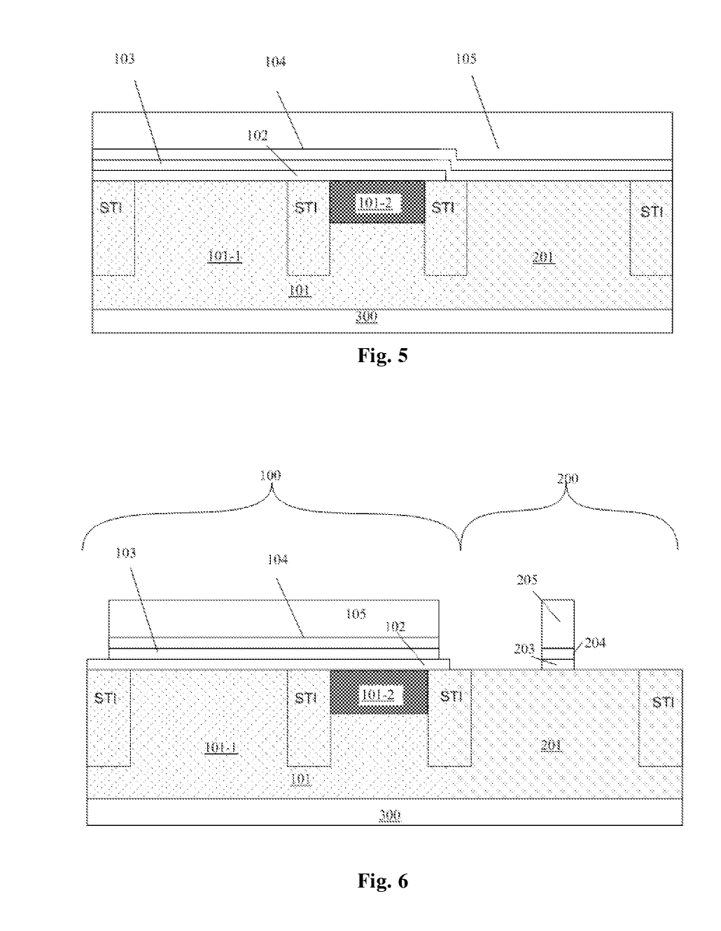

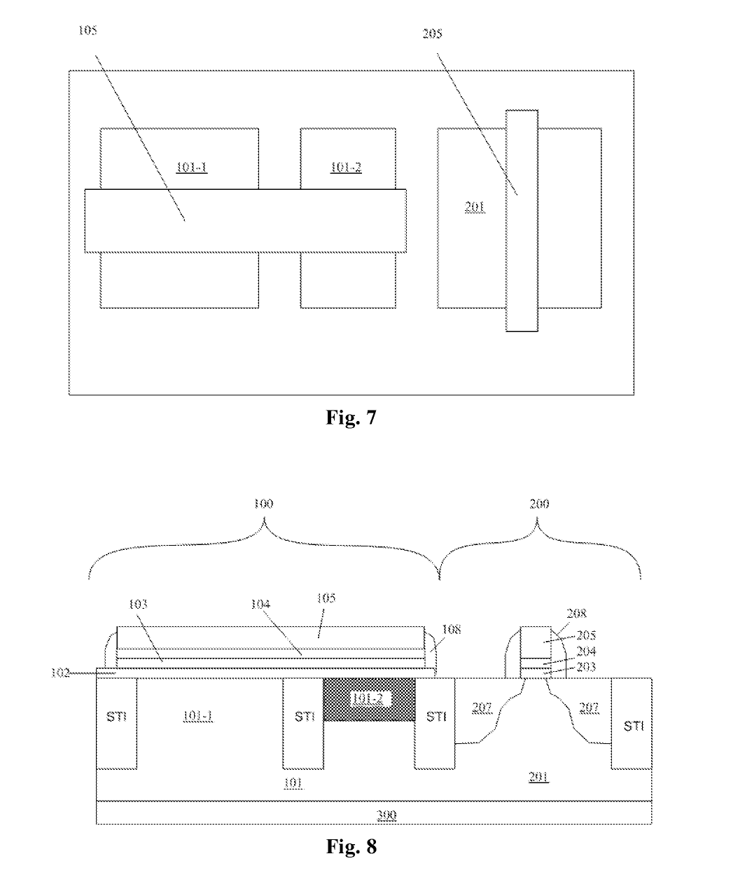

Then in step 3, a high-k gate dielectric layer 103 and a metal layer 104 are formed on the first doped well 101. A polysilicon layer 105 may be formed optionally. First, the high-k gate dielectric layer 103, the metal layer 104 and the polysilicon layer 105 can be formed on the entire substrate. The high-k gate dielectric layer 103 may be HfO₂ having a thickness of about 2-4 nm. The metal in the metal layer 104 may be TiN having a thickness of about 3-10 nm. The metal layer 104 may be, for example, any one or more of TaC, TiN, TaTbN, TaErN, TaYbN, TaSiN, HfSiN, MoSiN, RuTaₓ, NiTaₓ, MoNₓ, TiSiN, TiCN, TaAlC, TiAlN, TaN, PtSiₓ, Ni₃Si, Pt, Ru, Ir, Mo, HfRu and RuOₓ. Then as shown in FIGS. 6 and 7, a patterned photoresist is formed, and the polysilicon layer 105, the metal layer 104 and the high-k gate dielectric layer 103 are etched using a reactive ion etching (RIE) technology. Afterwards, the photoresist is removed.

In addition, the gate stack of the transistor area can be formed simultaneously with the formation of the gate stack of the flash memory area, as being compatible with the process flow of the transistor area.

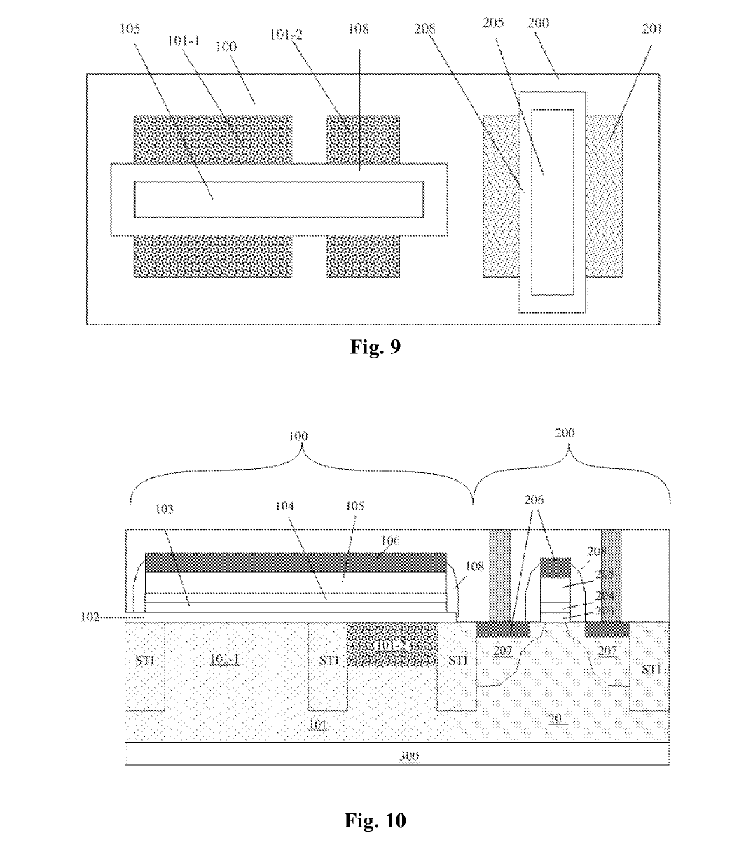

The embodiments according to the present invention have been described above in conjunction with the drawings. Optionally, a step 4 may be carried out thereafter, in which a source region 207 and a drain region 207 are formed in the transistor area 200 of the substrate 300, as shown in FIGS. 8 and 9. For example, the source region and the drain region are formed by forming a source/drain extension implantation, forming sidewall spacers 108 and 208 respectively at the sidewalls of the gate stacks of the flash memory area 100 and the transistor area 200, performing a source/drain implantation, and then performing a source/drain annealing process to activate the doped ions.

Optionally, a step 5 may be carried out after forming the source region and the drain region, in which a metal silicide layer, e.g. NiSi, is formed on the source and the drain of the transistor area 200 and on the gate stack of the flash memory area and the gate stack of the transistor area. Then subsequent processes are performed on the device. Specifically, an inter-layer dielectric layer is formed to cover the device, and metal contact areas are formed on the source region and the drain region of the transistor area, as shown in FIG. 10.

In the flash memory device obtained according to the embodiments of the present invention, the second region 101-2 functions as the controlling gate of the flash memory device, the polysilicon layer 105 functions as the floating gate, and the first region 101-1 functions as the source/drain region.

In addition, as shown in FIG. 9, source/drain contact holes can be made on both sides of the floating gate on 101-1 of the flash memory area, and gate contact holes can be made on 101-2, so that the storage function of the flash memory device can be realized, i.e. erasing and writing of electric charges on the floating gate can be realized by changing the voltage on the controlling gate.

In an embodiment of the present invention, polysilicon with better erasability is applied to the flash memory structure manufactured by the high-k gate dielectric metal gate process, so that the flash memory structure comprising the high-k gate dielectric metal gate can also be applied into the OTP device and can have better compatibility. Moreover, the flash memory and the transistor can be formed respectively, while using the same steps and performing these steps on the same material, which greatly reduces the complexity of the process and increases the production efficiency of the semiconductor device.

The above disclosed are merely the preferred embodiments of the present invention, and they certainly do not define the protection scope of the present invention. It shall be understood that equivalent changes made without departing from the spirit and scope defined by the appended claims of the present invention should fall within the scope of the present invention.

1. A flash memory device, comprising:
a semiconductor substrate; and
a flash memory area located on the semiconductor substrate;
wherein the flash memory area comprises:
a first doped well, which is divided into a first region and a second region by an isolation region,
the second region being doped with an impurity having an electrical conductivity opposite to that of the first doped well;
a high-k gate dielectric layer located on the first doped well; and
a metal layer located on the high-k gate dielectric layer.

2. The device according to claim 1, further comprising a polysilicon layer located on the metal layer.

3. The device according to claim 1, wherein if the first doped well is P-type doped, then the impurity doped in the second region is P, As or any combination thereof; and if the first doped well is N-type doped, then the impurity doped in the second region is B, Ga, In or any combination thereof.

4. (canceled)

5. The device according to claim 1, wherein the metal layer comprises one or more of TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni3Si, Pt, Ru, Ir, Mo, HfRu and RuOx.

6. The device according to claim 1, further comprising an oxide layer between the substrate and the high-k gate dielectric layer.

7-8. (canceled)

9. The device according to claim 1, further comprising a transistor area located on the semiconductor substrate.

10. The device according to claim 9, wherein the transistor area comprises:
a second doped well that is isolated from the first doped well by an isolation region;
a gate stack located on the second doped well; and
a source/drain region on both sides of the gate stack in the second doped well, wherein the gate stack comprises a high-k gate dielectric layer and a metal layer on the high-k gate dielectric layer.

11. The device according to claim 9, wherein the second doped well is doped with an impurity having an electrical conductivity opposite to that of the first doped well.

12. The device according to claim 10, wherein the gate stack further comprises:
a polysilicon layer located on the metal layer.

13. A method of manufacturing a flash memory device, comprising the steps of:
providing a semiconductor substrate;
forming a flash memory area on the substrate, the flash memory area comprising a first doped well, which is divided into a first region and a second region by an isolation region, the second region being doped with an impurity having an electrical conductivity opposite to that of the first doped well; and
forming a high-k gate dielectric layer and a metal layer in this order on the first doped well.

14. The method according to claim 13, wherein the step of forming the flash memory area comprises:
forming the isolation region in the substrate to isolate the first region from the second region, and performing ion implantation to the first region and the second region using an impurity of a first doping type to form the first doped well, and
performing ion implantation to the second region using an impurity of a second doping type that is opposite to the first doping type.

15. The method according to claim 10, further comprising a step of forming a polysilicon layer on the metal layer of the flash memory area.

16. The method according to claim 13, wherein if the first doped well is P-type doped, and then the impurity in the second region is P, As or any combination thereof; and if the first doped well is N-type doped, then the impurity in the second region is B, Ga, In or any combination thereof.

17. (canceled)

18. The method according to claim 13, wherein the metal layer comprises one or more of TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni3Si, Pt, Ru, Ir, Mo, HfRu and RuOx.

19. The method according to claim 13, further comprising a step of forming an oxide layer on the flash memory area before the step of forming the high-k gate dielectric layer on the first doped well.

20-21. (canceled)

22. The method according to claim 13, further comprising a step of forming a transistor area on the semiconductor substrate.

23. The method according to claim 22, wherein the step of forming the transistor area comprises:
forming a second doped well on the substrate, said second doped well being isolated from the first doped well by an isolation region;
forming a gate stack on the second doped well; and
forming a source/drain region on both sides of the gate stack in the second doped well,
wherein the gate stack comprises a high-k gate dielectric layer and a metal layer on the high-k gate dielectric layer.

24. The method according to claim 23, wherein the second doped well is doped with an impurity having an electrical conductivity opposite to that of the first doped well.

25. The method according to claim 23, wherein the step of forming the gate stack further comprises a step of forming a polysilicon layer on the metal layer.
